(19) United States
(12) Patent Application Publication
(10) Pub. No.: US 2012/0175782 A1
(43) Pub. Date: Jul. 12, 2012

(54) SEMICONDUCTOR PACKAGE AND METHOD OF MANUFACTURING THE SAME

(75) Inventors: Yunhyeok Im, Hwaseong-si (KR); Tae Hong Min, Gumi-si (KR); Taeje Cho, Hwaseong-si (KR)

(73) Assignee: SAMSUNG ELECTRONICS CO., LTD., Suwon-si (KR)

(21) Appl. No.: 13/347,270

(22) Filed: Jan. 10, 2012

(30) Foreign Application Priority Data
Jan. 10, 2011 (KR) 10-2011-0002401

(51) Int. Cl. H01L 23/522

(52) U.S. Cl. 257/774; 257/E23.145

(57) ABSTRACT

Provided are a semiconductor package and a method of manufacturing the same. a substrate including a first face and a second face, wherein the first and second faces face each other; a first ground pattern disposed on the first face; a second ground pattern disposed on the second face; a plurality of ground via plugs which connect the first ground pattern and the second ground pattern, wherein the plurality of ground via plugs penetrate the substrate; and a first aluminum oxide film interposed between the plurality of ground via plugs, wherein a ground voltage is applied to the plurality of ground via plugs. The semiconductor package may be manufactured using an anodic oxidation process.

### CROSS-REFERENCE TO RELATED APPLICATIONS

This application claims priority under 35 U.S.C. §119 of Korean Patent Application No. 10-2011-0002401, filed on Jan. 10, 2011, the entire content of which is hereby incorporated by reference.

### BACKGROUND

Apparatuses and methods consistent with the present inventive concept relate to semiconductor packages and methods of manufacturing the same.

As electronic devices become miniaturized, slimmer and with higher density, printed circuit boards are also becoming miniaturized and slimmer. A design of a printed circuit board has become complicated and techniques with high level of difficulty have been required because of a transmission and reception requirements of multi-function devices, and because of the huge amounts of data to be processed, coupled with the desired portability of electronic devices. As a result, demand for improved printed circuit boards have been increased. A power supply circuit, a ground circuit and a signal circuit are formed in the printed circuit board, and thus, demand for improved circuitry for printed circuit boards has also increased.

However, when transmitting an electrical signal through a power supply circuit or a signal circuit, noise generated from the power supply circuit or the signal circuit may have an adverse effect on neighboring circuits of the printed circuit board. Therefore, an improved printed circuit board design is desired.

### SUMMARY

One or more exemplary embodiments may overcome the above disadvantages and other disadvantages not described above. However, it is understood that one or more exemplary embodiments are not required to overcome the disadvantages described above, and may not overcome any of the problems described above.

According to an aspect of an exemplary embodiment, there is provided a semiconductor package which may include: a substrate comprising a first face and a second face, wherein the first and second faces face each other; a first ground pattern disposed on the first face; a second ground pattern disposed on the second face; a plurality of ground via plugs which connect the first ground pattern and the second ground pattern, wherein the plurality of ground via plugs penetrate the substrate; and a first aluminum oxide film interposed between the plurality of ground via plugs, wherein a ground voltage is applied to the plurality of ground via plugs.

A diameter of the ground via plug may be between about 10 nm and about 1 μm.

The semiconductor package may further include: a first signal pattern disposed on the first face and adjacent to the first ground pattern; a second signal pattern disposed on the second face and adjacent to the second ground pattern; a plurality of signal via plugs which penetrate the substrate and connect the first signal pattern and the second signal pattern; and a second aluminum oxide film interposed between the plurality of signal via plugs.

The first ground pattern and the second ground pattern may have a curved shape and substantially surround the first signal pattern and the second signal pattern, respectively, and wherein the first ground pattern and the second ground pattern vertically overlap.

The first signal pattern and the second signal pattern may vertically overlap and may have a substantially spiral shape, and wherein the first ground pattern and the second ground pattern may be disposed outside of the first signal pattern and the second signal pattern, respectively, and may have the spiral shape surrounding the first signal pattern and the second signal pattern.

The plurality of ground via plugs may be interconnected and side surfaces of the plurality of ground via plugs may be coplanar, and the plurality signal via plugs may be interconnected, and side surfaces of the signal via plugs may be coplanar.

The semiconductor package may further include: a first insulating film disposed on the first ground pattern, and wherein the first signal pattern is disposed on the first insulating film; and a second insulating film, wherein the second ground pattern is disposed on the second insulating film, wherein the second insulating film is disposed on the second signal pattern, wherein the plurality of signal via plugs penetrate the first insulating film, the substrate and the second insulating film, and connect the first signal pattern and the second signal pattern, and wherein the first ground pattern and the second ground pattern have a substantially circular shape and substantially surround end portions of the first signal pattern and the second signal pattern respectively.

The plurality of ground via plugs may include a plurality of sub via plugs which vertically overlap.

The semiconductor package may further include: plurality of dummy insulating via plugs which have a substantially same diameter as the ground via plugs, wherein the dummy insulating via plugs penetrate the substrate; and a third aluminum oxide film interposed between the plurality of dummy insulating via plugs.

The plurality of dummy insulating via plug may include one of an insulating solid and a gas.

The ground via plugs may be disposed in a substantially honeycomb-like shape.

The substrate may be one of an aluminum oxide template and an insulator.

The curved shape may be substantially a C character shape.

According to an aspect of an exemplary embodiment, there is provided a semiconductor package comprising: a substrate comprising a first face and a second face, wherein the first and second faces face each other; a first ground pattern disposed on the first face; a first signal pattern disposed on the first face and spaced apart from the first ground pattern; a second ground pattern disposed on the second face; a second signal pattern disposed on the second face and spaced apart from the second ground pattern; a ground via pattern which penetrates the substrate and connects the first ground pattern and the second ground pattern; and a plurality of signal via patterns which penetrate the substrate and connect the first signal pattern and the second signal pattern, wherein the first signal pattern, the second signal pattern and the signal via pattern vertically overlap and have a substantially spiral shape, and wherein the first ground pattern, the second ground pattern and the ground via pattern are disposed outside of the first signal pattern, the second signal pattern and the signal via pattern and have a substantially spiral shape and substantially surrounds the first signal pattern, the second signal pattern and the signal via pattern, respectively.

According to an aspect of an exemplary embodiment, there is provided a semiconductor package which may include: a substrate including a first face and a second face which face each other; a first ground pattern disposed on the first face; a second ground pattern disposed on the second face; a plurality of ground via plugs which connect the first ground pattern and the second ground pattern through the substrate; a first aluminum oxide film interposed between the plurality of ground via plugs; a first signal pattern disposed on the first face and adjacent to the first ground pattern; a second signal pattern disposed on the second face and adjacent to the second ground pattern; a plurality of signal via plugs which connect the first signal pattern and the second signal pattern through the substrate; and a second aluminum oxide film interposed between the plurality of signal via plugs, wherein a ground voltage is applied to the plurality of ground via plugs, and wherein the first ground pattern and the second ground pattern have a curved shape.

The curved shape may be substantially C-shaped.

### BRIEF DESCRIPTION OF THE FIGURES

The foregoing and other features of the present inventive concept will be apparent from the more particular description of preferred aspects of the present inventive concept, as illustrated in the accompanying drawings in which like reference characters refer to the same parts throughout the different views. The drawings are not necessarily to scale, emphasis instead being placed upon illustrating the principles of the present inventive concept. In the drawings, the thickness of layers and regions are exaggerated for clarity.

FIG. 1A is a top plan view illustrating a part of a semiconductor package in accordance with a first exemplary embodiment of the present inventive concept.

FIG. 1B is a perspective view of FIG. 1A.

FIG. 2 is a cross sectional view taken along the line I-I′ of FIG. 1A according to the first exemplary embodiment of the present inventive concept.

FIGS. 3 through 10 are cross sectional views illustrating a process of manufacturing a part of a semiconductor package having a cross section of FIG. 2.

FIG. 11 is a cross sectional view taken along the line I-I′ of FIG. 1A according to a second exemplary embodiment of the present inventive concept.

FIG. 12 is a cross sectional view taken along the line I-I′ of FIG. 1A according to a third exemplary embodiment of the present inventive concept.

FIG. 13 is a cross sectional view taken along the line I-I′ of FIG. 1A according to a fourth exemplary embodiment of the present inventive concept.

FIGS. 14 through 17 are cross sectional views illustrating a process of manufacturing a part of a semiconductor package having a cross section of FIG. 13.

FIG. 18A is a top plan view illustrating a part of a semiconductor package in accordance with a fifth exemplary embodiment of the present inventive concept.

FIG. 18B is a perspective view of FIG. 18A.

FIG. 19 is a cross sectional view taken along the line II-II′ of FIG. 18A.

FIGS. 20 through 24 are cross sectional views illustrating a process of manufacturing a part of a semiconductor package having a cross section of FIG. 19.

FIG. 25 is a cross sectional view illustrating a part of a semiconductor package in accordance with a first exemplary embodiment of the present inventive concept.

FIG. 26 is a top plan view illustrating a part of a semiconductor package in accordance with a seventh exemplary embodiment of the present inventive concept.

FIG. 27 is a cross sectional view taken along the line III-III′ of FIG. 26.

FIG. 28 is a top plan view illustrating a part of a semiconductor package in accordance with an eighth exemplary embodiment of the present inventive concept.

FIG. 29 is a top plan view illustrating a part of a semiconductor package in accordance with a ninth exemplary embodiment of the present inventive concept.

FIG. 30 is a cross sectional view taken along the line IV-IV′ of FIG. 29.

FIG. 31 is a cross sectional view of semiconductor package in accordance with a tenth exemplary embodiment of the present inventive concept.

FIG. 32 is a cross sectional view of semiconductor package in accordance with an eleventh exemplary embodiment of the present inventive concept.

FIG. 33 is a cross sectional view of semiconductor package in accordance with a twelfth exemplary embodiment of the present inventive concept.

FIG. 34 is a perspective view illustrating a part of a semiconductor package of FIG. 33.

FIG. 35 is a cross sectional view of a semiconductor package in accordance with a thirteenth exemplary embodiment of the present inventive concept.

FIG. 36 is a drawing illustrating an example of a package module including a semiconductor package to which a technology of the present inventive concept is applied.

FIG. 37 is a block diagram illustrating an example of an electronic device including a semiconductor package to which a technology of the present inventive concept is applied.

### DETAILED DESCRIPTION OF THE EXEMPLARY EMBODIMENTS

Exemplary embodiments of the present inventive concept will be described below in more detail with reference to the accompanying drawings. The exemplary embodiments of the present inventive concept may, however, be embodied in different forms and should not be constructed as limited to the exemplary embodiments set forth herein. Rather, these exemplary embodiments are provided so that this disclosure will be thorough and complete, and will fully convey the scope of the present inventive concept to those skilled in the art. In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

### First Exemplary Embodiment

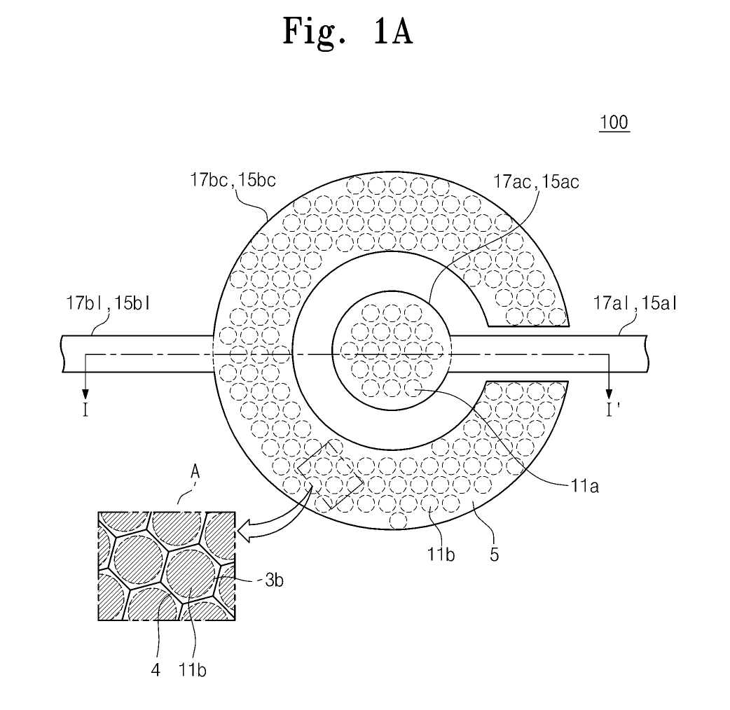

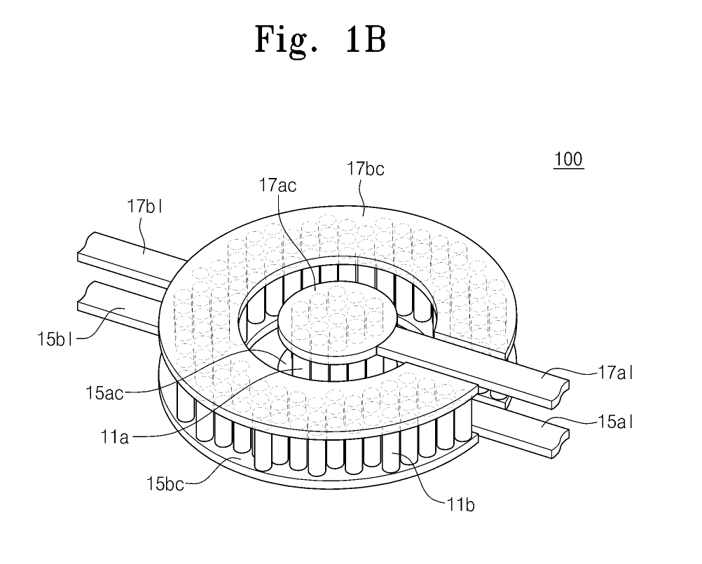

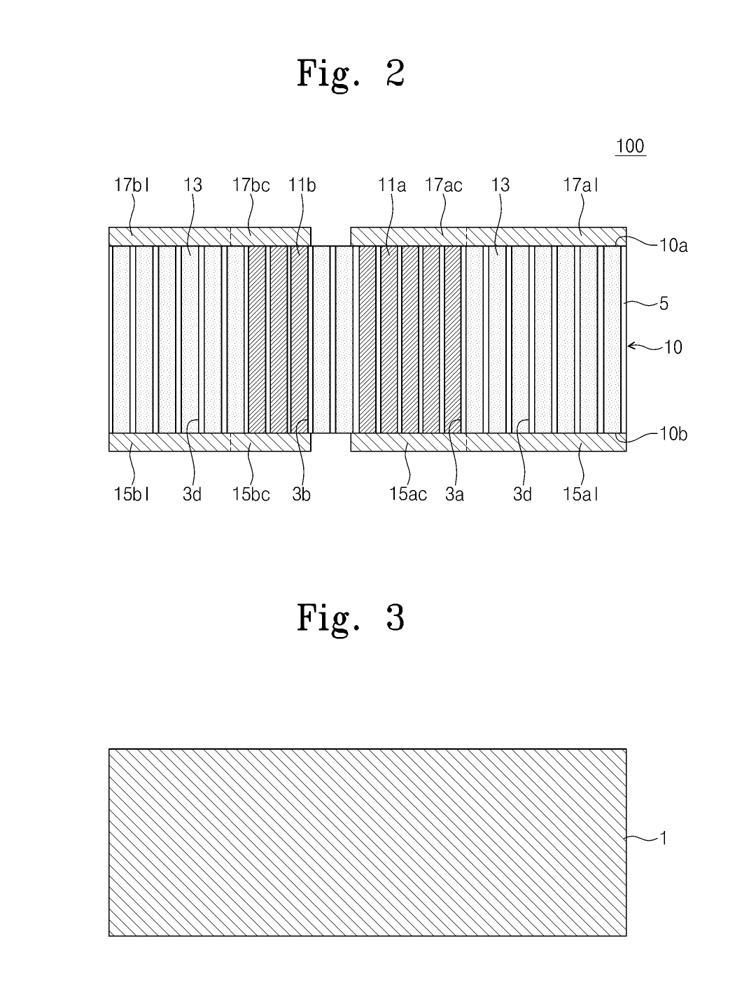

FIG. 1A is a top plan view illustrating a part of a semiconductor package in accordance with a first exemplary embodiment of the present inventive concept. FIG. 1B is a perspective view of FIG. 1A. FIG. 2 is a cross sectional view taken along the line I-I′ of FIG. 1A according to the first exemplary embodiment of the present inventive concept.

Referring to FIGS. 1A, 1B and 2, a semiconductor package 100 in accordance with the present exemplary embodiment may include a substrate 10 including a first face 10a and a second face 10b facing each other. The substrate 10 may be an aluminum oxide template. That is, the substrate 10 may be made of an aluminum oxide film 5 and may be a honeycomb shaped frame. A plurality of via holes 3a, 3b and 3d may be formed in the substrate 10. Each of the via holes 3a, 3b and 3d may be disposed at a center of an imaginary hexagon 4 constituting the honeycomb shape. The hexagon 4 is depicted to help our understanding but does not actually exist. The via holes 3a, 3b and 3d may include a signal via hole 3a, a ground via hole 3b and a dummy via hole 3d. An inside diameter of the via holes 3a, 3b and 3d may be about 10 nm-about 1 μm.

A first signal pattern 17ac and 17al and a first ground pattern 17bc and 17bl may be disposed on the first face 10a. The first signal pattern 17ac and 17al may include a first signal pattern circle portion 17ac and a first signal pattern line portion 17al. The first ground pattern 17bc and 17bl may include a first ground pattern circle portion 17bc and a first ground line portion 17bl. A second signal pattern 15ac and 15al and a second ground pattern 15bc and 15bl may be disposed on the second face 10b. The second signal pattern 15ac and 15al may include a second signal pattern circle portion 15ac and a second signal pattern line portion 15al. The second ground pattern 15bc and 15bl may include a second ground pattern circle portion 15bc and a second ground pattern line portion 15bl. The first signal pattern 17ac and 17al and the second signal pattern 15ac and 15al may vertically overlap each other and may have a same planar form. The first signal pattern 17ac and 17al and the second signal pattern 15ac and 15al may be a circle. The first ground pattern 17bc and 17bl and the second ground pattern 15bc and 15bl may vertically overlap and may have a same planar form. The first ground pattern 17bc and 17bl and the second ground pattern 15bc and 15bl may have a curved, C character shape surrounding the first signal pattern 17ac and 17al and the second signal pattern 15ac and 15al respectively.

A plurality of signal via plugs 11a may be disposed between the first signal pattern circle portion 17ac and the second signal pattern circle portion 15ac to electrically connect the first signal pattern circle portion 17ac and the second signal pattern circle portion 15ac. A plurality of ground via plugs 11b may be disposed between the first ground pattern circle portion 17bc and the second signal ground pattern circle portion 15bc to electrically connect the first ground pattern circle portion 17bc and the second signal ground pattern circle portion 15bc. The signal via plug 11a may be positioned in the signal via hole 3a. The ground via plug 11b may be positioned in the ground via hole 3b. The first signal pattern 17ac and 17al, the second signal pattern 15ac and 15al, the first ground patterns 17bc and 17bl, the second ground patterns 15bc and 15bl, the signal via plug 11a and the ground via plug 11b may be a conductive film and may be made of, for example, copper. A dummy insulating via plug 13 may be positioned in the dummy via hole 3d. The dummy insulating via plug 13 may be an insulating film.

A power supply voltage or a signal voltage may be supplied to the first signal patterns 17ac and 17al, the second signal patterns 15ac and 15al and the signal via plug 11a. A ground voltage may be supplied to the first ground patterns 17bc and 17bl, the second ground pattern 15bc and 15bl, and the ground via plug 11b. The signal via plug 11a, the ground via plug 11b and the dummy insulating via plug 13 may have a diameter of about 10 nm˜about 1 μm. Because a diameter of the signal via plug 11a and the ground via plug 11b is fine, the many signal via plugs 11a and the many ground via plugs 11b may be disposed per unit area. Thus, circuit patterns disposed on a substrate of semiconductor package may be highly integrated. Also, because the ground via plugs 11b disposed to surround the signal via plugs 11a are disposed in a curved, C character shape having a plurality of columns, they can effectively block electrical noises generated from the signal via plugs 11a.

Because the substrate 10 is an aluminum oxide template in the present exemplary embodiment, an aluminum oxide film 5 may be disposed between the signal via plugs 11a and between the ground via plugs 11b. Also, the aluminum oxide film 5 may be disposed between the dummy insulating via plugs 13. Because the aluminum oxide film 5 is interposed between the conductive via plugs 11a and 11b, a leakage current may be prevented and a signal speed may be increased compared with the case that a semiconductor film is interposed.

A part of the semiconductor package 100 illustrated in FIGS. 1A, 1B and 2 may be applied to a package substrate or an interposer.

FIGS. 3 through 10 are cross sectional views illustrating a process of manufacturing a part of a semiconductor package having a cross section of FIG. 2.

Referring to FIG. 3, an aluminum template 1 is prepared.

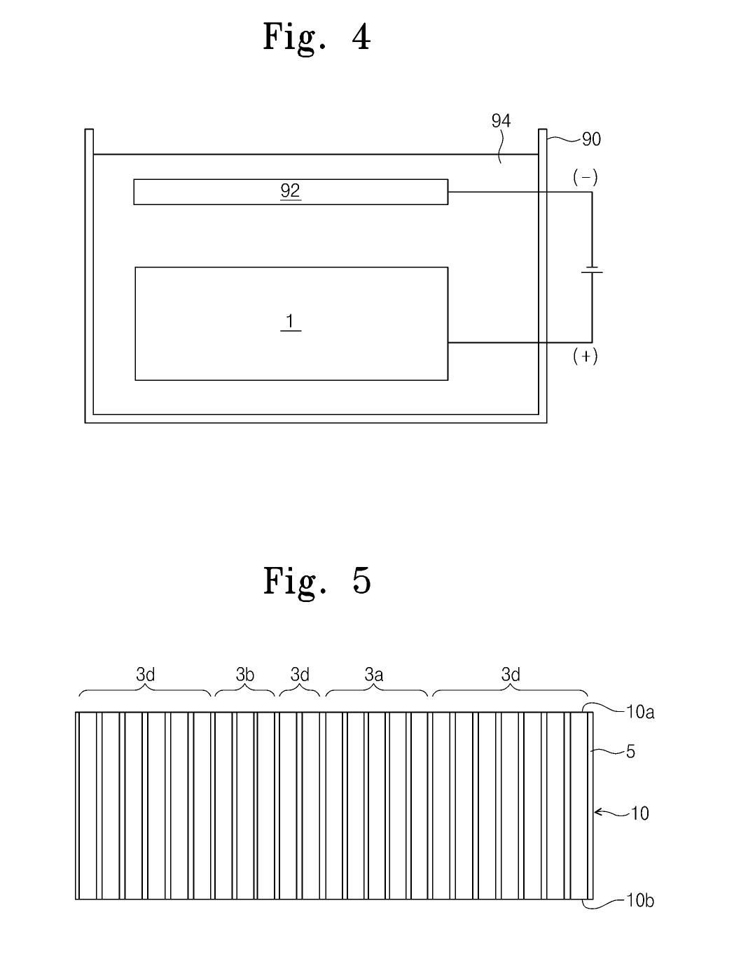

Referring to FIGS. 4 and 5, via holes 3a, 3b and 3d are formed by performing an anodic oxidation process while converting the aluminum template 1 into an aluminum oxide. More specifically, the aluminum template 1 is put in a vessel filled with electrolyte 94. A platinum plate 92 is disposed on the aluminum template 1 in the vessel 90. The electrolyte 94 may be oxalic acid of 0.3M. A positive polarity is connected to the aluminum template 1 and a negative polarity is connected to the platinum plate 92. In early anodic oxidation, pores are formed vertically on a surface of the aluminum template 1 but the pores are irregularly arranged. However, due to a stress by an increase of volume when aluminum is converted into an aluminum oxide film, the pores are self aligned in a form capable of minimizing a stress over time. Since an arrangement capable of making the best use of a given space is a hexagonal close-packing structure, the pores are arranged in a hexagonal shape and consequently, a hexagonal structure like a honeycomb is formed. If the anodic oxidation process is used, a very deep via hole having an aspect ratio of 1000 to 1 can be formed. As a result, the via holes 3a, 3b and 3d can be formed and the substrate made of an aluminum oxide template can be formed. The substrate 10 may have a first face 10a and a second face 10b facing each other. An inside diameter of the via holes 3a, 3b and 3d may be about 10 nm˜about 1 μm. The via holes 3a, 3b and 3d may include a signal via hole 3a, a ground via hole 3b and a dummy via hole 3d.

Referring to FIG. 6, a mask pattern 7 opening the signal via hole 3a and the ground via hole 3b and covering the remaining part may be formed on the second face 10b of the substrate 10. The mask pattern 7 may be formed of a film having a poor step coverage characteristic not so as to fill the via holes 3a, 3b and 3d.

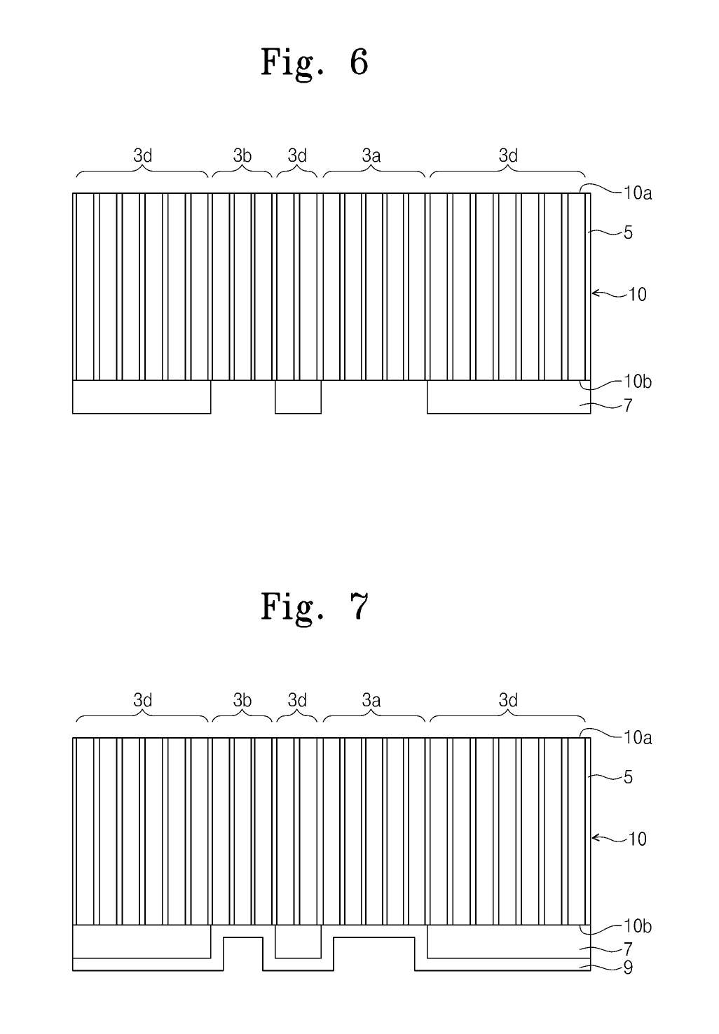

Referring to FIG. 7, a seed film 9 is formed so as to conform to the second face 10b of the substrate 10. The seed film 9 may be formed by a physical vapor deposition process. The physical vapor deposition process has a low step coverage characteristic and thereby it is difficult that the signal via hole 3a and the ground via hole 3b are filled by the physical vapor deposition process.

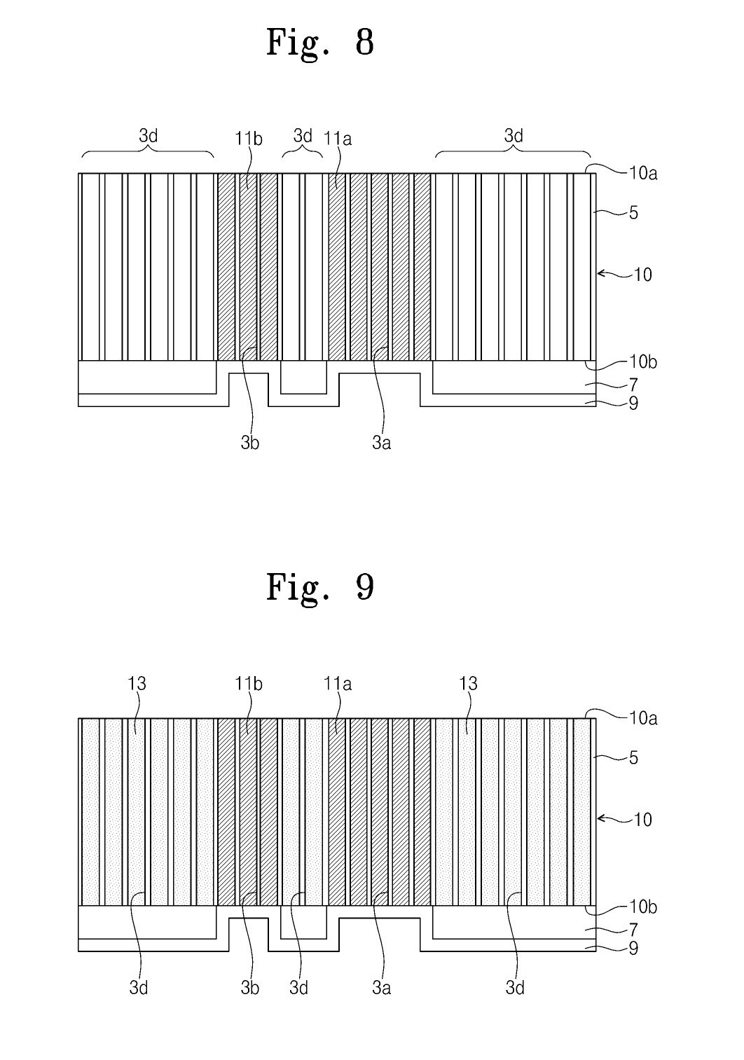

Referring to FIG. 8, a plating film 9 is grown from the seed film 9 of the second face 10b by performing a plating process to form a signal via plug 11a and a ground via plug 11b filling the signal via hole 3a and the ground via hole 3b respectively. Because the seed film 9 is not disposed on bottom surfaces of the dummy via holes 3d and the bottom surfaces of the dummy via holes 3d are covered with the mask pattern 7, a plating film may not be grown in the dummy via holes 3d.

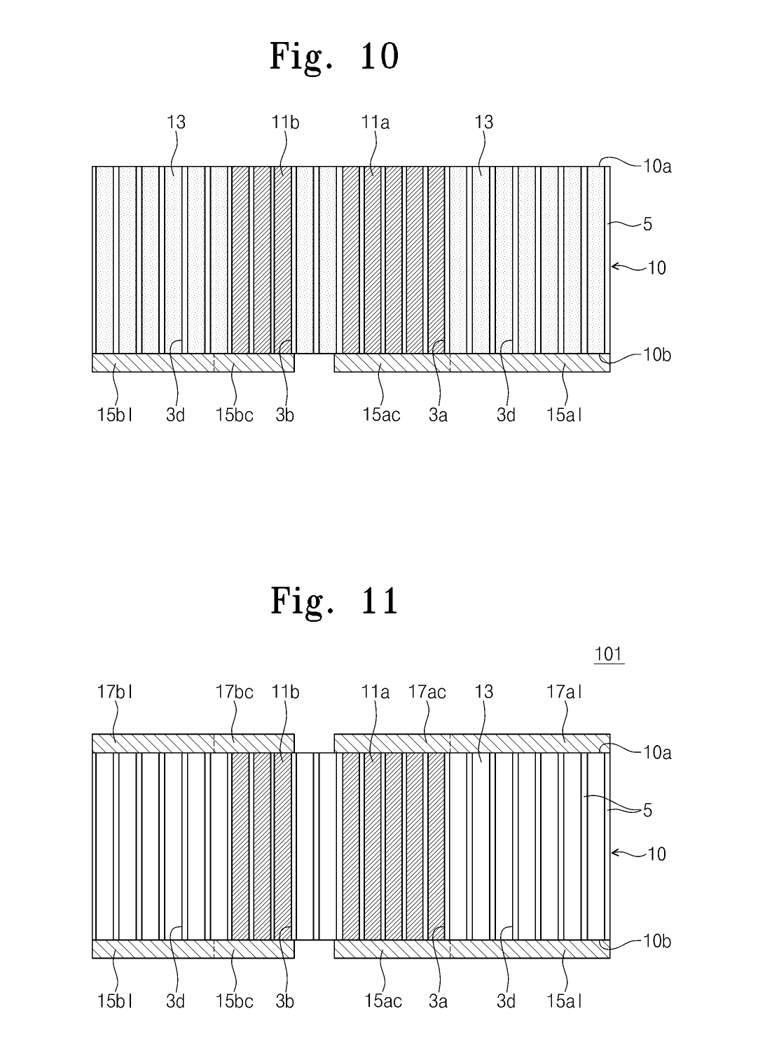

Referring to FIG. 9, an insulating film may fill the insides of the dummy via holes 3d and the insulating film is planarized, i.e., flattened to form a dummy insulating via plug 13. The dummy insulating via plug 13 may be formed of a film having a good step coverage characteristic. The dummy insulating via plug 13 may be formed of an insulating solid.

Referring to FIG. 10, the mask pattern 7 and the seed film 9 are removed. A second signal pattern 15ac and 15al and a second ground pattern 15bc and 15bl are formed on the second face 10b of the substrate 10.

Referring back to FIG. 2, a part of the semiconductor package 100 may be completed by forming a first signal pattern 17ac and 17al and a first ground pattern 17bc and 17bl on the first face 10a of the substrate 10.

### Second Exemplary Embodiment

FIG. 11 is a cross sectional view taken along the line I-I′ of FIG. 1A according to a second exemplary embodiment of the present inventive concept.

Referring to FIG. 11, in a semiconductor package 101 in accordance with the second exemplary embodiment, a dummy insulating via plug 13 may formed of an insulating gas. The dummy insulating via plug 13 may be an air. That is, the inside of the dummy via hole 3d may not be filled with an insulating solid but may be vacant. The semiconductor package 101 may be formed by omitting the process of FIG. 10 among the manufacturing processes of the first exemplary embodiment. The structures and manufacturing processes except for the process of FIG. 10 may be the same with the first exemplary embodiment or may be similar to the first exemplary embodiment.

### Third Exemplary Embodiment

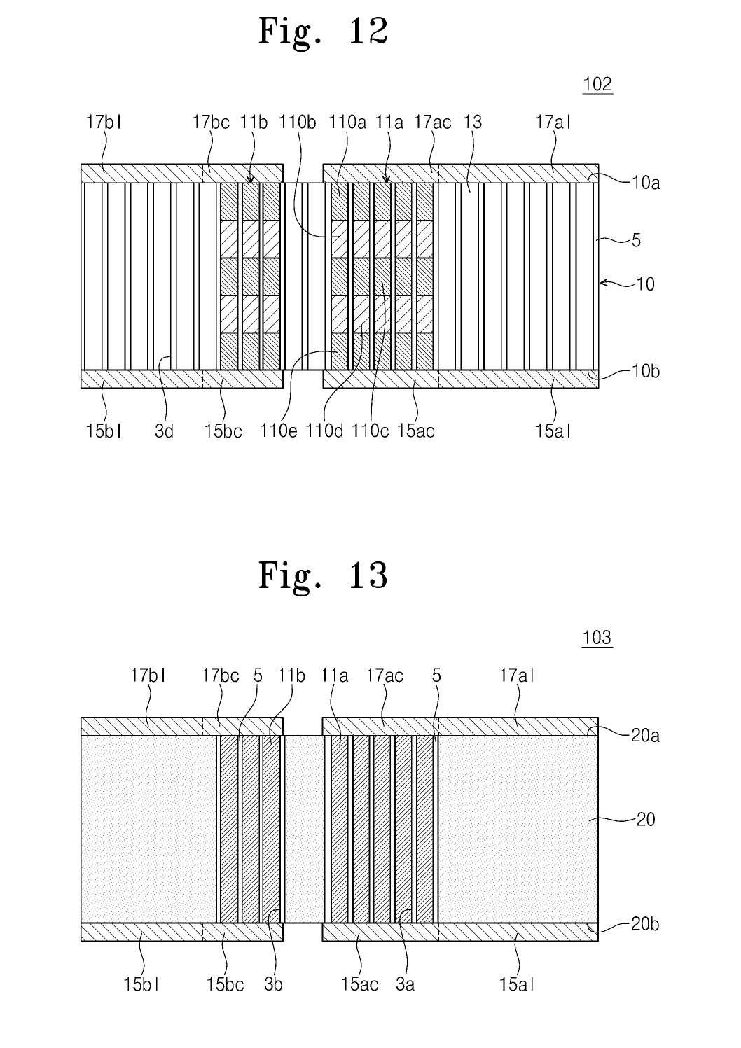

FIG. 12 is a cross sectional view taken along the line I-I′ of FIG. 1A according to a third exemplary embodiment of the present inventive concept.

Referring to FIG. 12, in a semiconductor package 102 in accordance with the third exemplary embodiment, a signal via plug 11a and a ground via plug 11b may be constituted by a plurality of sub via plugs 110a through 110e that vertically overlaps each other. The plurality of sub via plugs 110a through 110e may include a first sub via plug 110a, a second sub via plug 110b, a third sub via plug 110c, a fourth sub via plug 110d and a fifth sub via plug 110e from above to below. The first sub via plug 110a and the fifth sub via plug 110e may be made of gold that does not form an oxide. The second sub via plug 110b and the fourth sub via plug 110d may be made of nickel improving an interface junction characteristic and preventing an electro-migration. The third sub via plug 110c may be made of copper that has a good electric conductivity and is cheap. The plurality of sub via plugs 110a through 110e may be formed by performing a plating process while changing the electrolytes in the process of FIG. 9 of the first exemplary embodiment. The structures and manufacturing processes except for the process of FIG. 9 may be the same with the first exemplary embodiment or may be similar to the first exemplary embodiment.

### Fourth Exemplary Embodiment

FIG. 13 is a cross sectional view taken along the line I-I′ of FIG. 1A according to a fourth exemplary embodiment of the present inventive concept.

Referring to FIG. 13, a semiconductor package 103 in accordance with the fourth exemplary embodiment may include a substrate 20. The substrate 20 may be an insulator or a semiconductor. In the case that the substrate 20 is a semiconductor, although not illustrated in the drawing, transistors may be formed on the substrate 20. The substrate 20 does not include the dummy via hole 3d, the dummy insulating via plug 13 and the aluminum oxide film 5 interposed between the dummy insulating via plugs 13 that are illustrated in the first exemplary embodiment. The substrate 20 may not be an aluminum oxide template. The substrate 20 may be made of an insulating plastic. The structures except those things may be the same with the first exemplary embodiment or may be similar to the first exemplary embodiment.

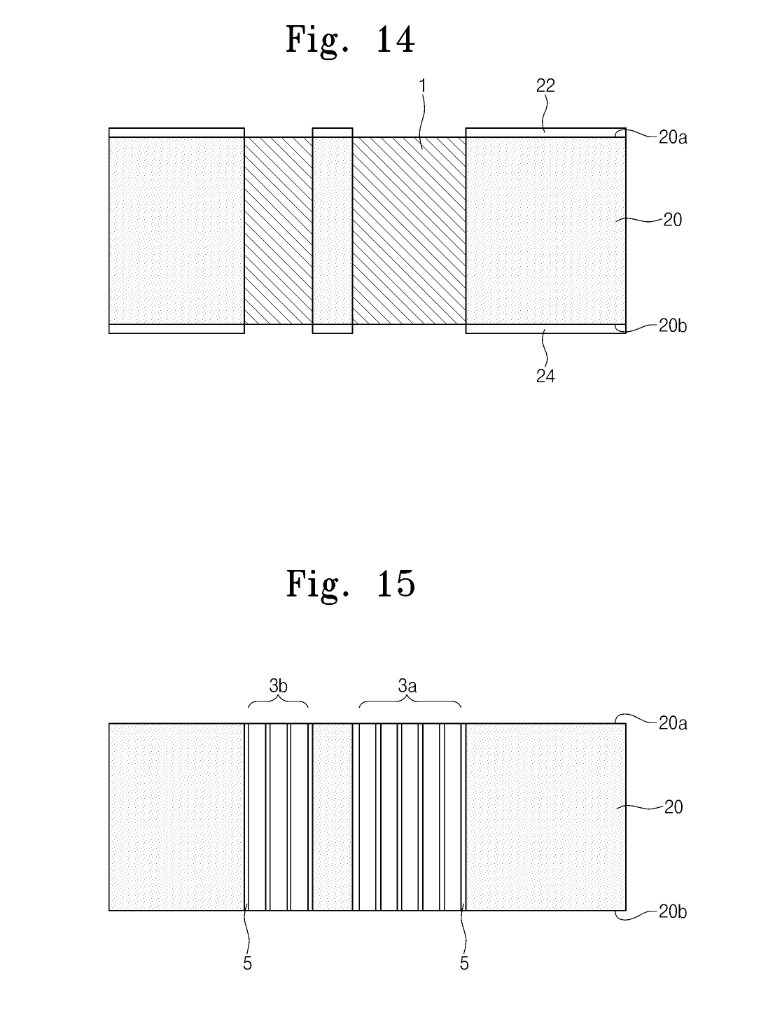

FIGS. 14 through 17 are cross sectional views illustrating a process of manufacturing a part of a semiconductor package having a cross section of FIG. 13.

Referring to FIG. 14, a substrate 20 made of a template is prepared. The substrate 20 may include a first face 20a and a second face 20b facing each other. A first mask pattern 22 and a second mask pattern 24 are formed in the first face 20a and the second face 20b respectively. The first mask pattern 22 and the second mask pattern 24 may define regions in which a signal via plug and a ground via plug are to be formed. A part of the substrate 20 defined by the first mask pattern 22 and the second mask pattern 24 is removed to be filled with an aluminum film 1.

Referring to FIG. 15, the first and second mask patterns 22 and 24 are removed. A positive polarity is connected to the aluminum film 1 and the anodic oxidation process disclosed in FIG. 3 of the first exemplary embodiment is performed on the aluminum film 1 to convert the aluminum film 1 into an aluminum oxide film 5 including a plurality of signal via holes 3a and ground via holes 3b.

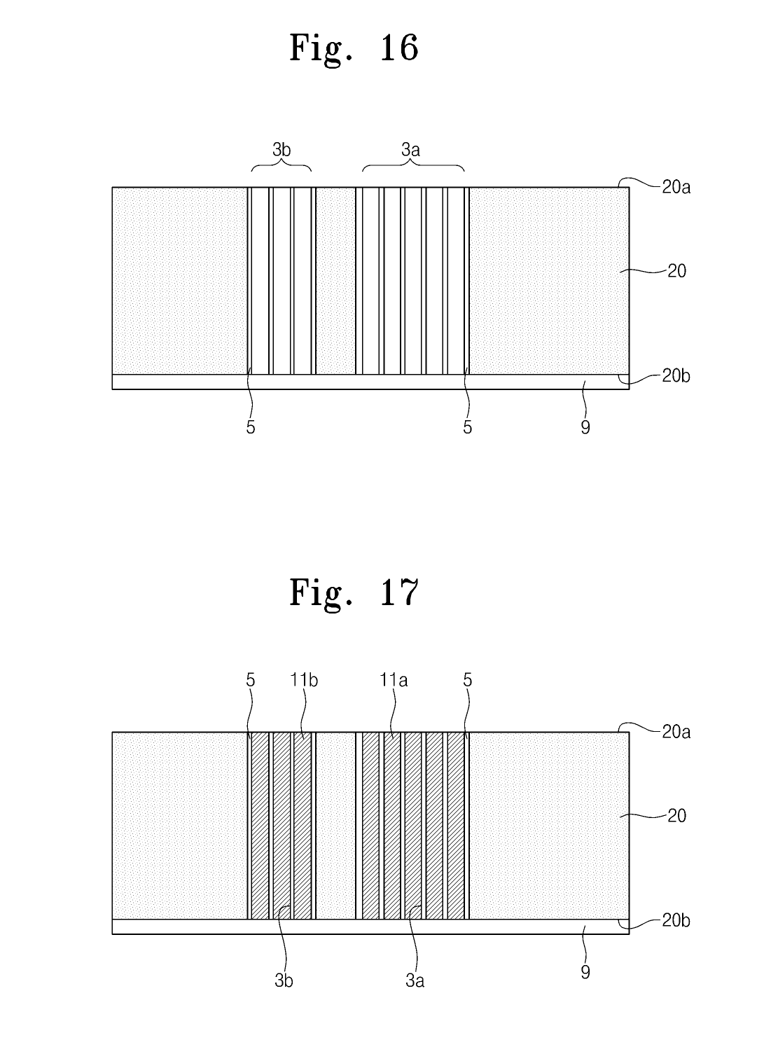

Referring to FIG. 16, a seed film 9 is formed on the second face 20b of the substrate 20.

Referring to FIG. 17, a plating film is grown from the seed film 9 by performing a plating process to form a signal via plug 11a and a ground via plug 11b filling the signal via hole 3a and the ground via hole 3b respectively.

Referring back to FIG. 13, the seed film 9 is removed. A first signal pattern 17ac and 17al and a first ground pattern 17bc and 17bl are formed on the first face 20a of the substrate 20 and a second signal pattern 15ac and 15al and a second ground pattern 15bc and 15bl are formed on the second face 20b of the substrate 20. As a result, the second package 103 of FIG. 13 may be completed.

### Fifth Exemplary Embodiment

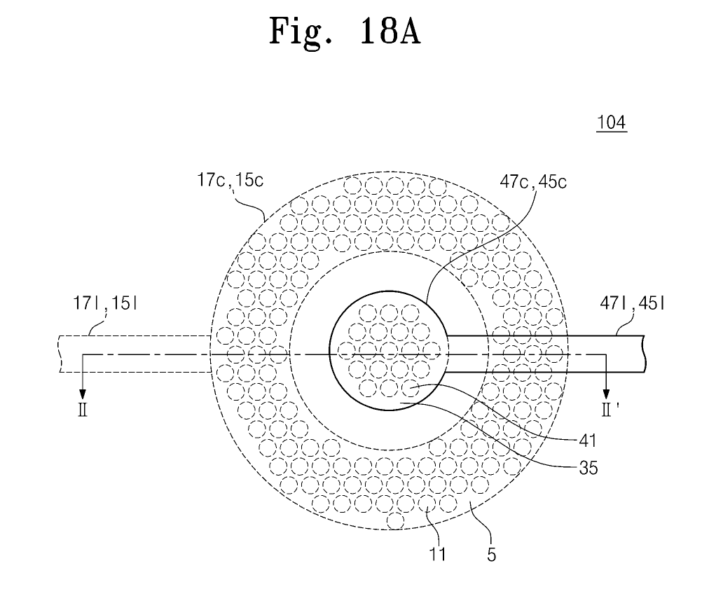

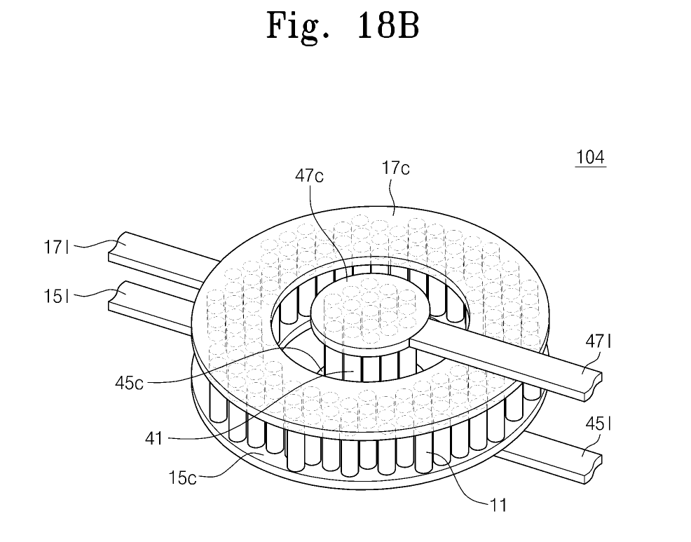

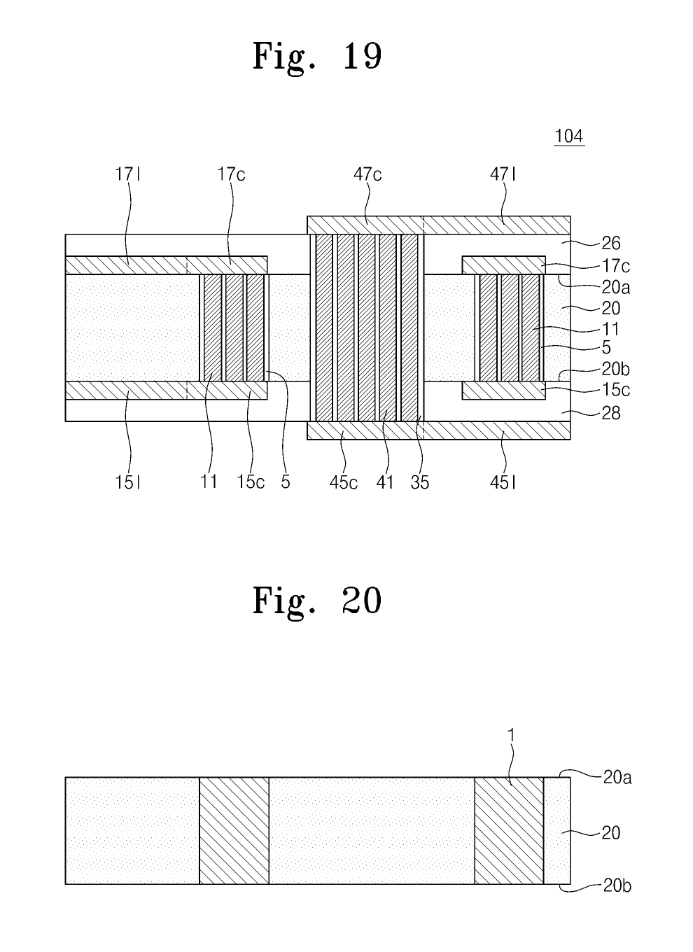

FIG. 18A is a top plan view illustrating a part of a semiconductor package in accordance with a fifth exemplary embodiment of the present inventive concept. FIG. 18B is a perspective view of FIG. 18A. FIG. 19 is a cross sectional view taken along the line II-II′ of FIG. 18A.

Referring to FIGS. 18A, 18B and 19, in a semiconductor package 104 in accordance with the fifth exemplary embodiment, a first signal pattern 47c and 47l and a first ground pattern 17c and 17l are disposed on different layers from each other and a second signal pattern 45c and 45l and a second ground pattern 15c and 15l are also disposed on different layers from each other. A first ground pattern circle portion 17c and a second ground pattern circle portion 15c may be a circle surrounding the first signal circle portion 47c and the second signal pattern circle portion 45c. A ground via plug 11 may penetrate the substrate 20 to electrically connect the first ground pattern circle portion 17c and the second ground pattern circle portion 15c. The first ground pattern 17c and 17l is disposed on the first face 20a of the substrate 20. The first face 20a and the first ground pattern 17c and 17l are covered with a first insulating film 26. The first signal pattern 47c and 47l is disposed on the first insulating film 26. The second ground pattern 15c and 15l is disposed on the second face 20b of the substrate 20. The second face 20b and the second ground pattern 15c and 15l are covered with a second insulating film 28. The second signal pattern 45c and 45l is disposed on a bottom surface of the second insulating film 28. Signal via plugs 41 penetrate the first insulating film 26, the substrate 20 and the second insulating film 28 to connect the first signal pattern circle portion 47c and the second signal pattern circle portion 45c. The structures except those things may be the same with the first exemplary embodiment or may be similar to the first exemplary embodiment.

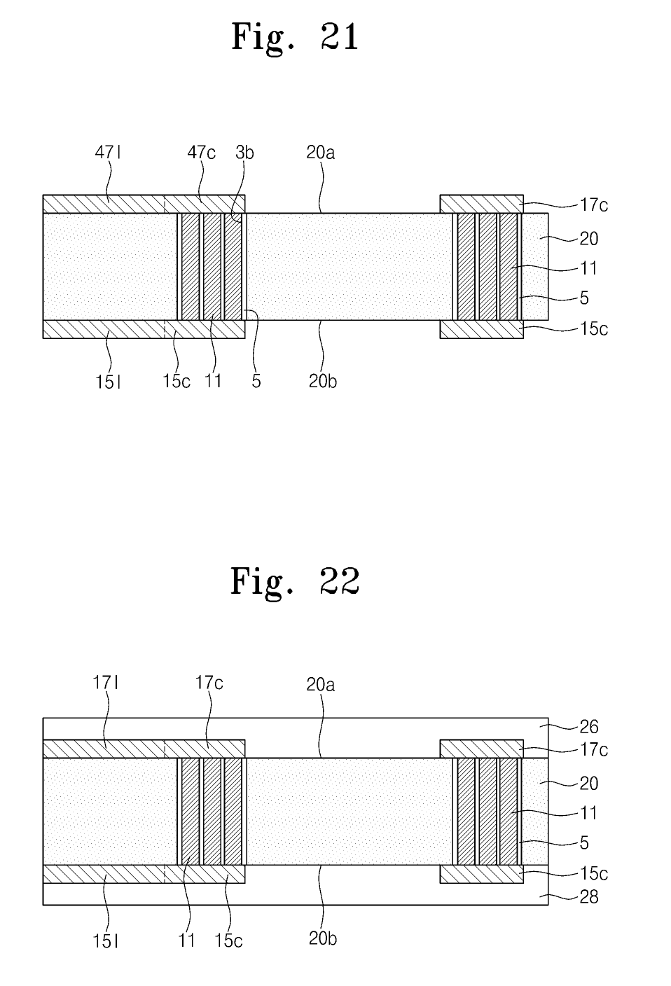

FIGS. 20 through 24 are cross sectional views illustrating a process of manufacturing a part of a semiconductor package having a cross section of FIG. 19.

Referring to FIG. 20, a substrate 20 made of a template is prepared. The substrate 20 may include a first face 20a and a second face 20b facing each other. A region in which a ground via plug is to be formed is defined by removing a part of the substrate 20 and the region is filled with a first aluminum film 1.

Referring to FIG. 21, a positive polarity is connected to the first aluminum film 1 and an anodic oxidation process is performed on the first aluminum film 1 to form a first aluminum oxide film 5 having a ground via hole 3b. A seed film is formed on the second face 20b and a plating process is performed to form a ground via plug 11 filling the ground via hole 3b. The seed film is removed and a first ground pattern 17c and 17l and a second ground pattern 15c and 15l are formed on the first face 20a and the second face 20b of the substrate 20 respectively.

Referring to FIG. 22, a first insulating film 26 and a second insulating film 28 are formed on the first face 20a and the second face 20b of the substrate 20 respectively.

Referring to FIG. 23, a region in which a signal via plug is to be formed is defined by removing a part of the first insulating film 26, the substrate 20 and the second insulating film 28 and a second aluminum film 31 is formed in the region.

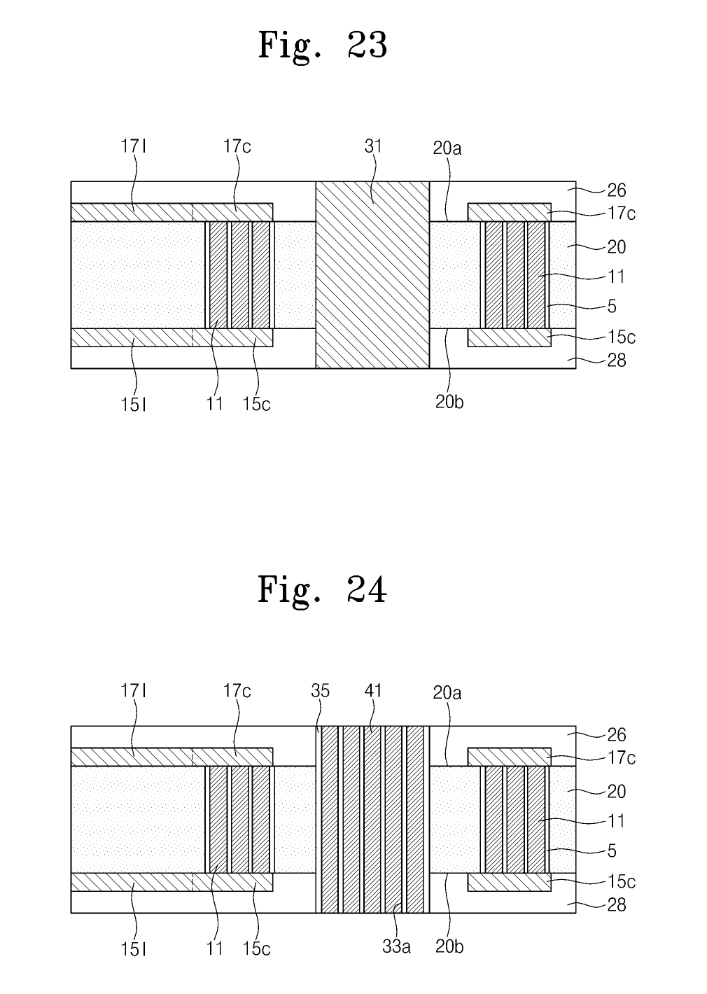

Referring to FIG. 24, a positive polarity is connected to the second aluminum film 31 and an anodic oxidation process is performed on the second aluminum film 31 to form a second aluminum oxide film 35 having a signal via hole 33a. A seed film is formed on a bottom surface of the second insulating film 28 and a plating process is performed to form a signal via plug 41 filling the signal via hole 33a.

Referring to FIG. 19, the seed film is removed to form a first signal pattern 47c and 47l and a second signal pattern 45c and 45l on the first insulating film 26 and a bottom surface of the second insulating film 28 respectively. As a result, the semiconductor package of FIG. 19 can be completed. The structures except those things may be the same with the first exemplary embodiment or may be similar to the first exemplary embodiment.

### Sixth Exemplary Embodiment

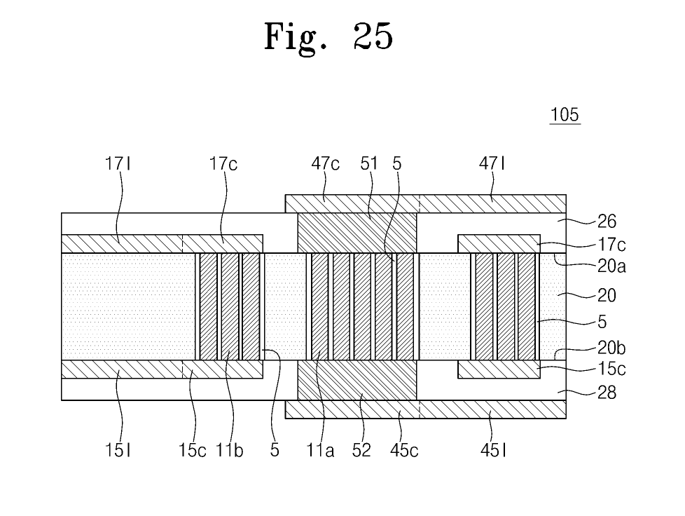

FIG. 25 is a cross sectional view illustrating a part of a semiconductor package in accordance with a first exemplary embodiment of the present inventive concept.

Referring to FIG. 25, in a semiconductor package 105 in accordance with the sixth exemplary embodiment, a signal via plug 11a may have the same height as the ground via plug 11b. A first conductive pattern 51 penetrating a first insulating film 26 is interposed between the signal via plug 11a and a first signal pattern circle portion 47c and a second conductive pattern 52 penetrating a second insulating film 28 is interposed between the signal via plug 11 a and a second signal pattern circle portion 45c.

The semiconductor package 105 may be formed by following methods. First, a plurality of signal via plugs 11a and ground via plugs 11b penetrating a substrate 20 is formed and a first ground pattern 17c and 17l and a second ground pattern 15c and 15l are formed on a first face 20a and a second face 20b of the substrate 20 respectively. A first insulating film 26 covering the first face 20a of the substrate 20 is formed. The first insulating film 26 is patterned to form a first trench exposing a top surface of the signal via plug 11a and the first trench is filled with a conductive material and then a planarization process is performed on the conductive material to form the first conductive pattern 51. A second insulating film 28 covering the second face 20b of the substrate 20 is formed. The second insulating film 28 is patterned to form a second trench exposing a bottom surface of the signal via plug 11a. The second trench is filled with a conductive material and then a planarization process is performed on the conductive material to form the second conductive pattern 52. The structures except those things may be the same with the fifth exemplary embodiment or may be similar to the fifth exemplary embodiment.

### Seventh Exemplary Embodiment

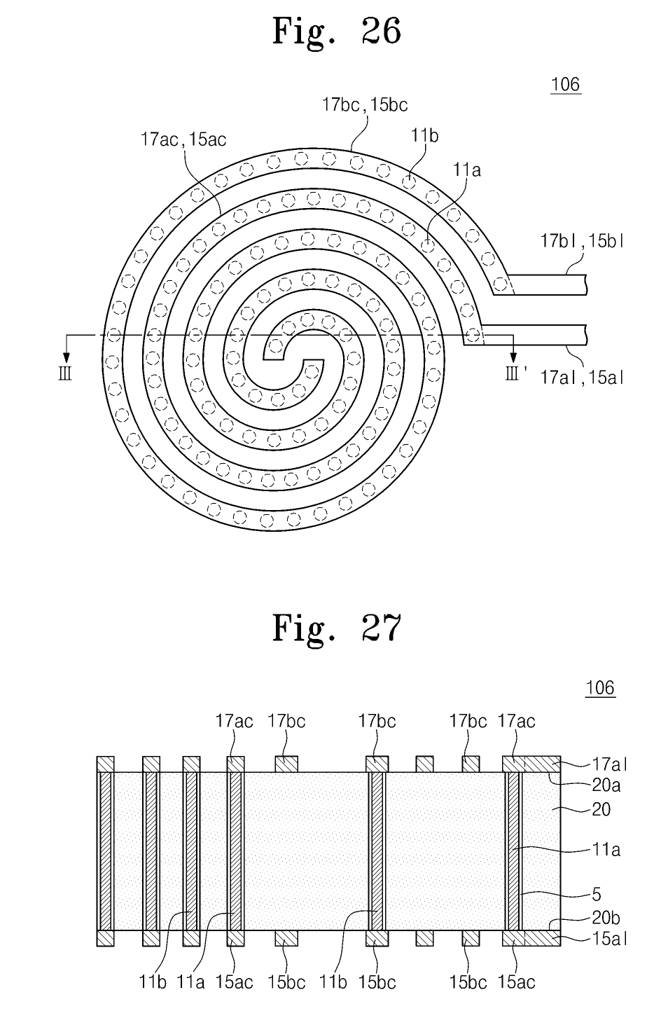

FIG. 26 is a top plan view illustrating a part of a semiconductor package in accordance with a seventh exemplary embodiment of the present inventive concept. FIG. 27 is a cross sectional view taken along the line III-III′ of FIG. 26.

Referring to FIGS. 26 and 27, in a semiconductor package 106 in accordance with the seventh exemplary embodiment, a first signal pattern circle portion 17ac and a second signal pattern circle portion 15ac are vertically overlap each other and have a same spiral, i.e., whirlpool-like shape. A first ground pattern circle portion 17bc and a second signal pattern circle portion 15bc are disposed outside the first signal pattern circle portion 17ac and the second signal pattern circle portion 15ac respectively and have a spiral shape surrounding the first signal pattern circle portion 17ac and the second signal pattern circle portion 15ac.

A plurality of signal via plugs 11a penetrating a substrate 20 may be disposed between the first signal pattern circle portion 17ac and the second signal pattern circle portion 15ac to electrically connect the first signal pattern circle portion 17ac and the second signal pattern circle portion 15ac. A plurality of ground via plugs 11b penetrating a substrate 20 may be disposed between the first ground pattern circle portion 17bc and the second ground pattern circle portion 15bc to electrically connect the first ground pattern circle portion 17bc and the second ground pattern circle portion 15bc. An aluminum oxide film 5 is interposed between the ground via plug 11b and the substrate 20. The ground via plugs 11b may be disposed in a line along the first ground pattern circle portion 17bc and the signal via plugs 11a may be disposed in a line along the first signal pattern circle portion 17ac. The structures except those things may be the same with the fourth exemplary embodiment or may be similar to the fourth exemplary embodiment.

The semiconductor package 106 in accordance with the seventh exemplary embodiment may be formed using the method described with reference to FIGS. 14 through 17 of the fourth exemplary embodiment.

### Eighth Exemplary Embodiment

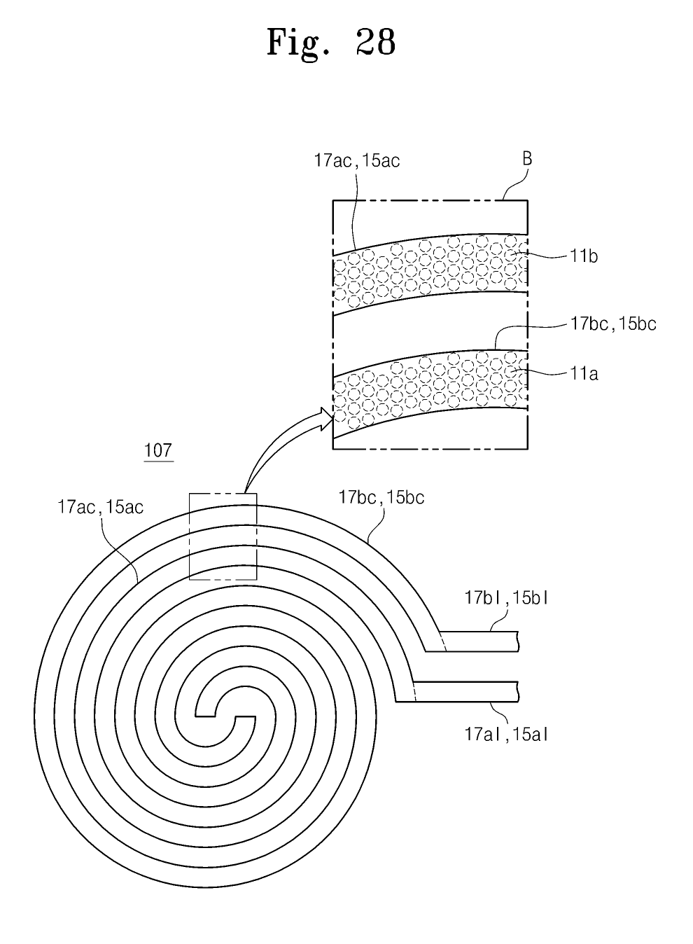

FIG. 28 is a top plan view illustrating a part of a semiconductor package in accordance with an eighth exemplary embodiment of the present inventive concept.

Referring to FIG. 28, in a semiconductor package 107 in accordance with the eighth exemplary embodiment, a plurality of ground via plugs 11b is disposed along a first ground pattern circle portion 17bc and a plurality of signal via plugs 11a is disposed along a first signal pattern circle portion 17ac. The structures except those things may be the same with the seventh exemplary embodiment or may be similar to the seventh exemplary embodiment.

### Ninth Exemplary Embodiment

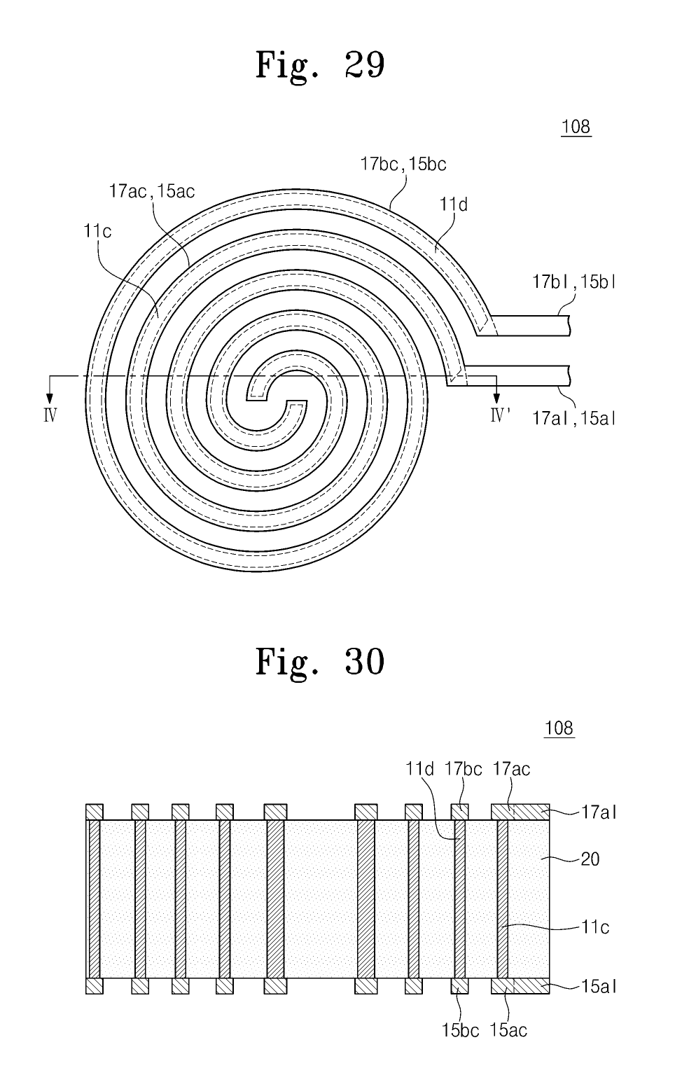

FIG. 29 is a top plan view illustrating a part of a semiconductor package in accordance with a ninth exemplary embodiment of the present inventive concept. FIG. 30 is a cross sectional view taken along the line IV-IV′ of FIG. 29.

Referring to FIGS. 29 and 30, in a semiconductor package 108 in accordance with the ninth exemplary embodiment, a signal via pattern 11c penetrating a substrate 20 is disposed between a first signal pattern circle portion 17ac and a second signal pattern circle portion 15ac to electrically connect the first signal pattern circle portion 17ac and the second signal pattern circle portion 15ac. The signal via pattern 11c has a spiral line shape like the first signal pattern circle portion 17ac. Also, a ground via pattern 11d penetrating the substrate 20 is disposed between a first ground pattern circle portion 17bc and a second ground pattern circle portion 15bc to electrically connect the first ground pattern circle portion 17bc and the second ground pattern circle portion 15bc. The ground via pattern 11d has a spiral line shape like the first ground pattern circle portion 17bc. An aluminum oxide film is not interposed between the signal via pattern 11c and the substrate 20 and between the ground via pattern 11d and the substrate 20. The signal via pattern 11c and the ground via pattern 11d may be made of a conductive film such as copper or aluminum. The structures except those things may be the same with the seventh exemplary embodiment or may be similar to the seventh exemplary embodiment. A process of forming the semiconductor package 108 in accordance with the ninth exemplary embodiment may not use an anodic oxidation process.

### Tenth Exemplary Embodiment

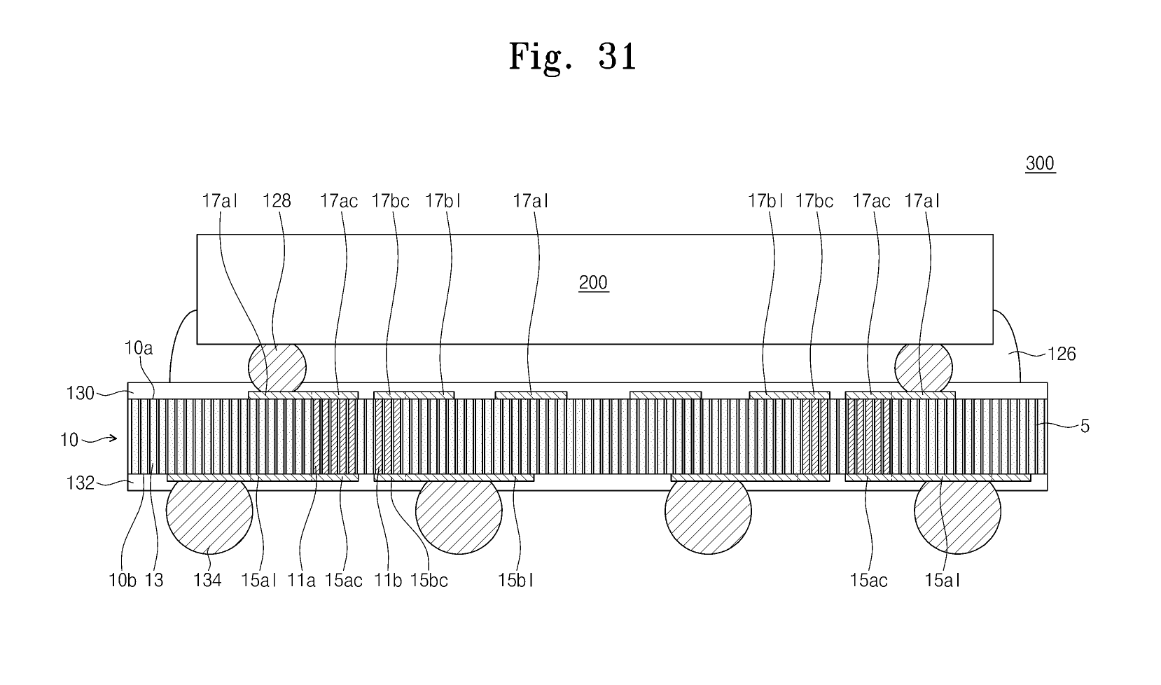

FIG. 31 is a cross sectional view of semiconductor package in accordance with a tenth exemplary embodiment of the present inventive concept.

Referring to FIG. 31, a semiconductor package 300 in accordance with the tenth exemplary embodiment includes a part of the semiconductor package 100 of the first exemplary embodiment. More specifically, the semiconductor package 300 may include a substrate 10 made of an aluminum oxide template. A signal via plug 11a, a ground via plug 11b and a dummy insulating via plug 13 penetrate the substrate 10. A first protective film 130 covering a first signal pattern 17ac and 17al and a first ground pattern 17bc and 17bl may be disposed on a first face 10a of the substrate 10. A second protective film 132 covering a second signal pattern 15ac and 15al and a second ground pattern 15bc and 15bl is disposed on a second face 10b of the substrate 10. A semiconductor chip 200 is mounted on the first face 10a. The semiconductor chip 200 may be electrically connected to a predetermined portion of the first signal pattern line portion 17al through an inner solder ball 128. A space between the semiconductor chip 200 and the substrate 10 may be filled with an underfill resin film. An outer solder ball 134 may adhere to predetermined portions of the second signal pattern line portion 15al and the second ground pattern line portion 15bl. The structures except those things may be the same with the first exemplary embodiment or may be similar to the first exemplary embodiment.

### Eleventh Exemplary Embodiment

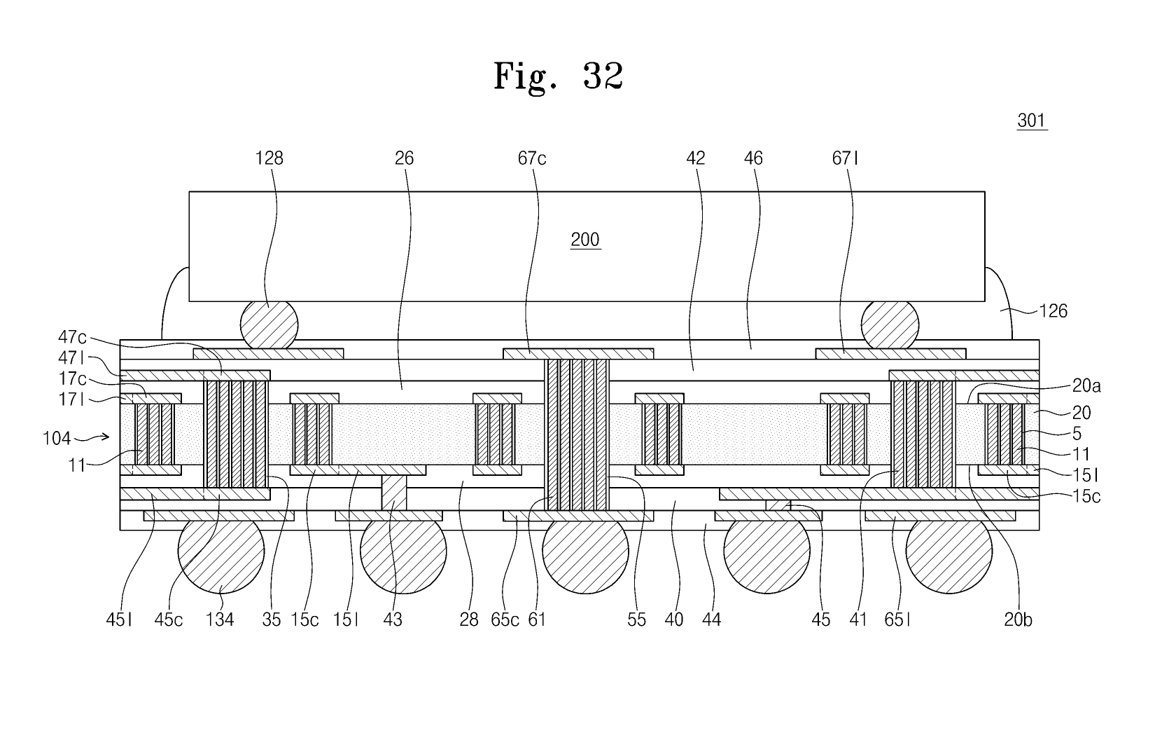

FIG. 32 is a cross sectional view of semiconductor package in accordance with an eleventh exemplary embodiment of the present inventive concept.

Referring to FIG. 32, a semiconductor package 301 in accordance with the eleventh exemplary embodiment includes a part of the semiconductor package 104 of the fifth exemplary embodiment. More specifically, the semiconductor package 301 includes a ground via plug 11 penetrating a substrate 20. A first ground via pattern 17c and 17l is disposed on a first face 20a of the substrate 20 and a second ground via pattern 15c and 15l is disposed on a second face 20b of the substrate 20. A first insulating film 26 is disposed on the first face 20a to cover the first ground via pattern 17c and 17l. A first signal pattern 47c and 47l is disposed on the first insulating film 26. A second insulating film 28 is disposed on the second face 20b. A second signal pattern 45c and 45l is disposed on the second insulating film 28. A first signal via plug 41 penetrates the first insulating film 26, the substrate 20 and the second insulating film 28 to electrically connect the first signal pattern 47c and 47l and the second signal pattern 45c and 45l. A third insulating film 42 is disposed on the first insulating film 26 to cover the first signal pattern 47c and 47l. A third signal pattern 67c and 67l is disposed on the third insulating film 42. The third signal pattern 67c and 67l is covered with a first protective film 46. A fourth insulating film 40 is disposed on the second insulating film 28. A fourth signal pattern 65c and 65l and a second protective film 44 are disposed on the fourth insulating film 40. A second signal via plug 61 penetrates the third insulating film 42, the first insulating film 26, the substrate 20, the second insulating film 28 and the fourth insulating film 40 to connect the third signal pattern 67c and 67l and the fourth signal pattern 65c and 65l. Aluminum oxide films 5, 35 and 55 are interposed between the via plugs 11, 41 and 61. Predetermined portions of a first ground pattern line portion 15l and a fourth signal pattern line portion 65l may be connected to each other by a first connection via plug 43. Predetermined portions of a second signal pattern line portion 45l and the fourth signal pattern line portion 65l may be connected to each other by a second connection via plug 45. The structures except those things may be the same with the tenth exemplary embodiment or may be similar to the tenth exemplary embodiment.

### Twelfth Exemplary Embodiment

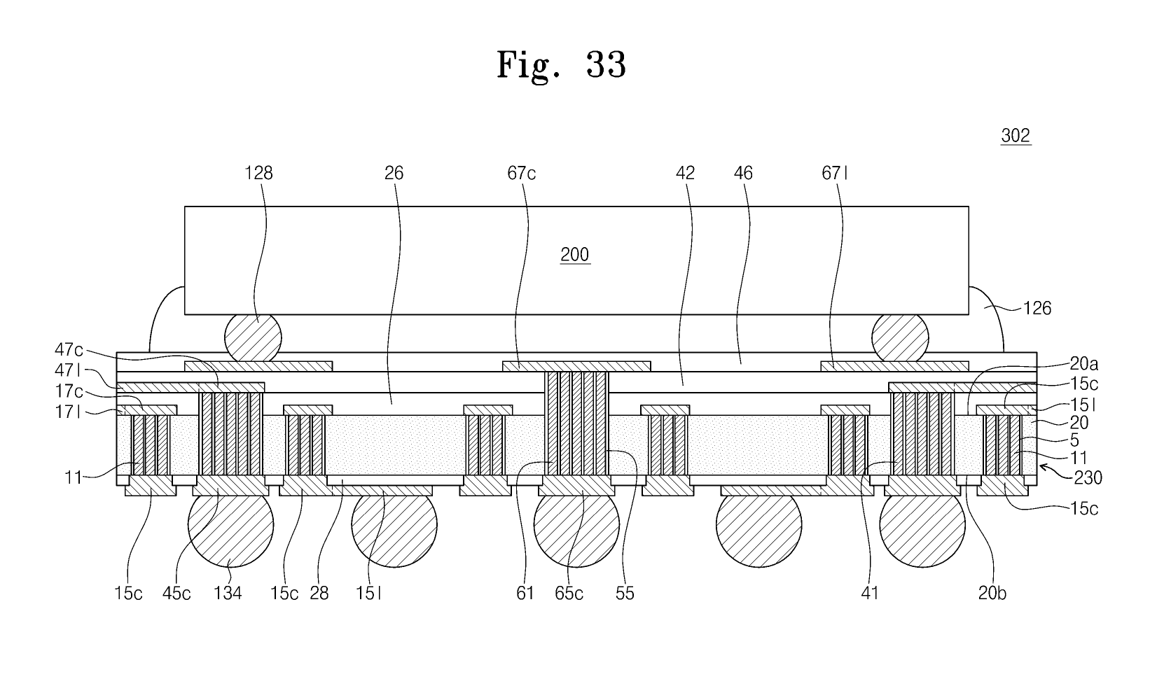

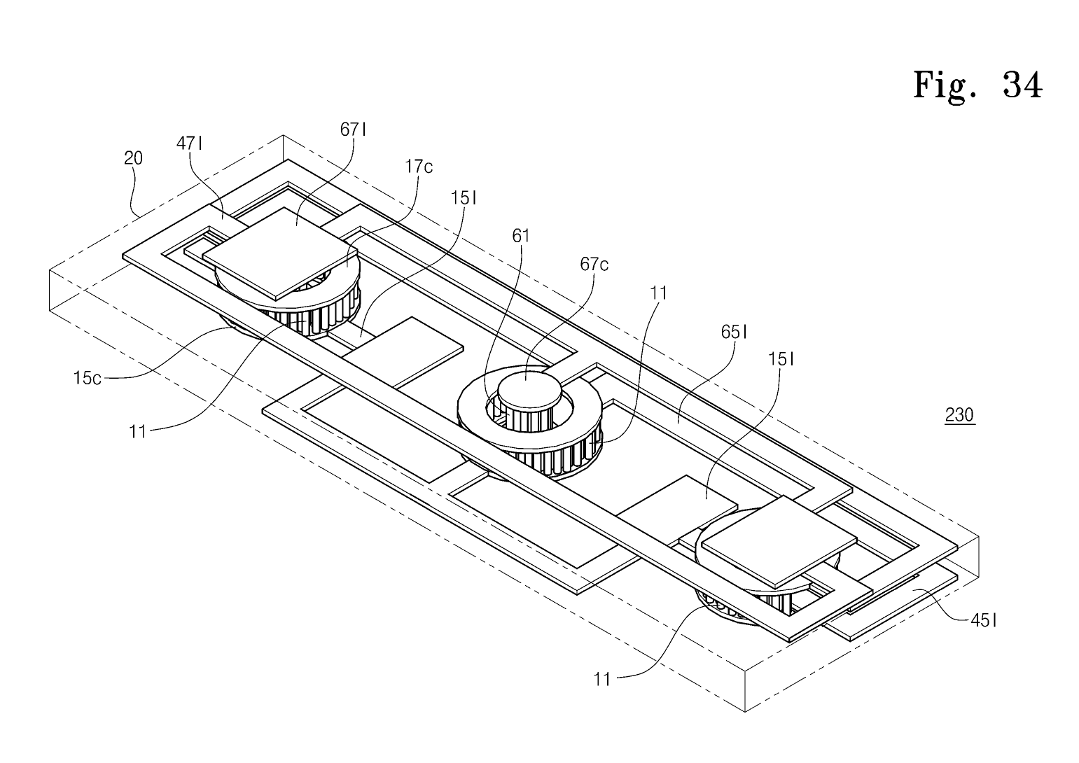

FIG. 33 is a cross sectional view of a semiconductor package in accordance with a twelfth exemplary embodiment of the present inventive concept. FIG. 34 is a perspective view illustrating a package substrate 230 of a semiconductor chip 200 which is a part of the semiconductor package of FIG. 33.

Referring to FIGS. 33 and 34, in a package substrate 230 included in a semiconductor package 302 in accordance with the twelfth exemplary embodiment, a ground via plug 11 penetrates a substrate 20 including a first face 20a and a second face 20b. a first ground pattern 17l and 17c, a first insulating film 26, a first signal pattern 47l and 47c, a third insulating film 42, a third signal pattern 67l and 67c and a protective film 46 are disposed on the first face 20a. A second insulating film 28, a second ground pattern 15c and 15l, a second signal pattern 45c and 45l and a fourth signal pattern 65c and 65l are disposed on the second face 20b. Top surfaces of the second insulating film 28, the second ground pattern 15c and 15l, the second signal pattern 45c and 45l and the fourth signal pattern 65c and 65l are coplanar with one another. A ground via plug 11 penetrates the substrate 20 to electrically the first ground pattern 17l and 17c and the second ground pattern 15c and 15l. A first signal via plug 41 penetrates the first insulating film 26 and the substrate 20 to electrically connect the first signal pattern 47l and 47c and the second signal pattern 45c and 45l. A second signal via plug 61 penetrates the third insulating film 42, the first insulating film 26 and the substrate 20 to electrically connect the third signal pattern 67l and 67c and the fourth signal pattern 65c and 65l. The ground via plug 11 may be disposed to surround the first signal via plug 41 and the second signal via plug 61. The structures except those things may be the same with the eleventh exemplary embodiment or may be similar to the eleventh exemplary embodiment.

The package substrate 230 illustrated in FIG. 34 may be used as an interposer being disposed between a package substrate and a semiconductor chip.

### Thirteenth Exemplary Embodiment

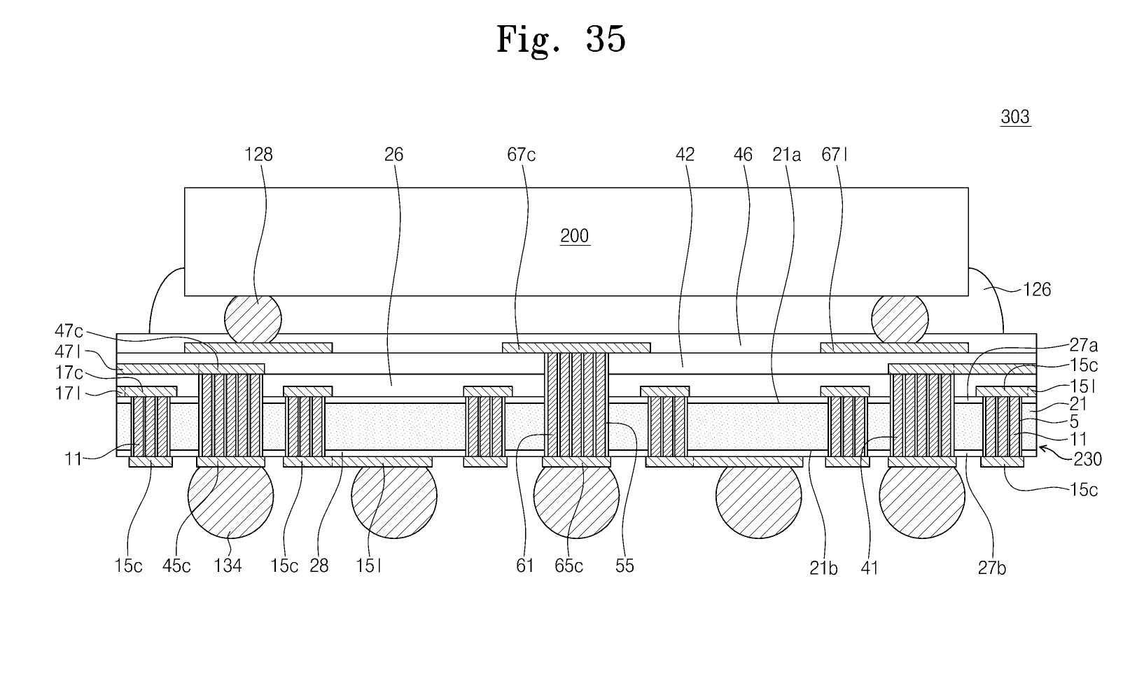

FIG. 35 is a cross sectional view of a semiconductor package in accordance with a thirteenth exemplary embodiment of the present inventive concept.

Referring to FIG. 13, a semiconductor package 303 in accordance with the thirteenth exemplary embodiment includes a substrate 21. The substrate 21 may be made of an aluminum template. The substrate 21 may include a first face 21a and a second face 21b facing each other. The first face 21a and the second face 21b are covered with a first substrate insulating film 27a and a second substrate insulating film 27b. The first substrate insulating film 27a and the second substrate insulating film 27b may be made of an aluminum oxide film. A first ground pattern 17l and 17c, a first insulating film 26, a first signal pattern 47l and 47c, a third insulating film 42, a third signal pattern 67l and 67c and a protective film 46 are disposed on the first substrate insulating film 27a. A second ground pattern 15c and 15l, a second signal pattern 45c and a fourth signal pattern 65c are disposed on the second substrate insulating film 27b.

The structures except those things may be the same with the twelfth exemplary embodiment or may be similar to the twelfth exemplary embodiment.

In a modified exemplary embodiment of the thirteenth exemplary embodiment, the first substrate insulating film 27a may not exist and the substrate 21 and the first ground pattern 17l and 17c may be in contact with each other.

In another modified exemplary embodiment of the thirteenth exemplary embodiment, the aluminum oxide film may also be on a side of the substrate 21. Accordingly, top, bottom and side surfaces of the substrate 21 may be surrounded by the aluminum oxide film.

The semiconductor package technologies described above may be applied to various types of semiconductor devices and package modules including the semiconductor devices.

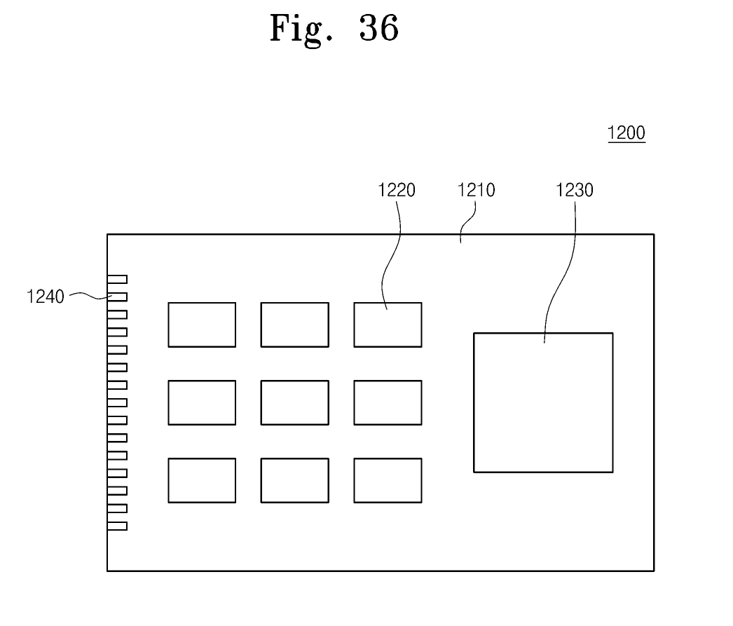

FIG. 36 is a drawing illustrating an example of a package module including a semiconductor package to which a technology of the present inventive concept is applied.

Referring to FIG. 36, a package module 1200 may be provided as a type of semiconductor integrated circuit chip 1220 and a type of semiconductor integrated circuit chip 1230 packaged with a quad flat package (QFP). The package module 1200 may be formed by installing the semiconductor integrated circuit chips 1220 and 1230 to which the semiconductor package technologies are applied on a substrate 1210. The package module 1200 may be connected to an external electronic device through external connection terminals disposed on one side of the substrate 1210.

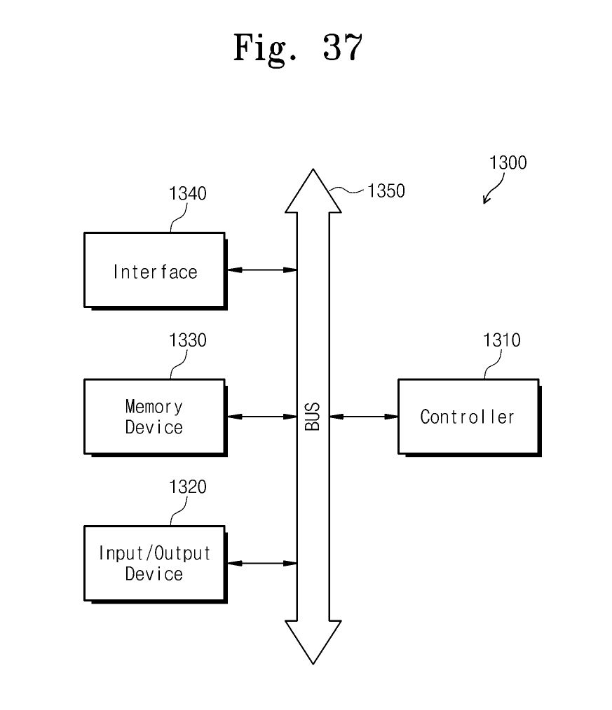

The semiconductor package technologies described above may be applied to an electronic system. FIG. 37 is a block diagram illustrating an example of an electronic device including a semiconductor package to which a technology of the present inventive concept is applied.

Referring to FIG. 37, an electronic system 1300 may include a controller 1310, an input/output device 1320 and a memory device 1330. The controller 1310, the input/output device 1320 and the memory device 1330 may be connected to one another through a bus 1350. The bus may be a path through which data move. For instance, the controller 1310 may include at least one of a micro processor, a digital signal processor, a microcontroller and a logic device having a function similar to the micro processor, the digital signal processor and the microcontroller. The controller 1310 and the memory device 1330 may include a semiconductor package in accordance with the present inventive concept. The input/output device 1320 may include at least one selected from a keypad, a keyboard and a display device. The memory device 1330 is a data storage device. The memory device 1330 may store data and/or an instruction executed by the controller 1310. The memory device 1330 may include volatile memory devices and/or nonvolatile memory devices. The memory device 1330 may be constituted by a flash memory. For example, flash memories to which the technologies of the present inventive concept are applied may be built in data processing systems such as a mobile device or a desk top computer. The flash memory may be constituted by a solid state disk (SSD). In this case, the electronic system 1300 can stably store huge amounts of data in the flash memory system. The electronic system 1300 may further include an interface 340 to transmit data to a communication network or receive data from a communication network. The interface 1340 may be a wire type and or a wireless type. The interface 1340 may include an antenna or a wire/wireless transceiver. The electronic system 1300 may further include an application chip set, a camera image processor (CIS) and an input/output device.

The electronic system 1300 may be embodied by a mobile system, a personnel computer, an industrial computer or a logic system performing a variety of functions. For instance, the mobile system may be one of a personal digital assistant (PDA), a portable computer, a web tablet, a mobile phone, a wireless phone, a laptop computer, a memory card, a digital music system and a data transmission/receipt system. In the case that the electronic system 1300 is a equipment which can perform a wireless communication, the electronic system 1300 may be used in a communication interface protocol of a third generation such as CDMA, GSM, NADC, E-TDMA, CDMA2000.

A semiconductor package in accordance with the present inventive concept includes a ground via plug disposed to surround a signal via plug, thereby preventing an electrical noise from affecting adjacent circuits.

A ground via plug included in the semiconductor package of the present inventive concept has a fine diameter of about 10 nm˜1 μm and thereby it may be advantageous in high integration of semiconductor package.

A semiconductor package in accordance with the present inventive concept includes an aluminum oxide template, thereby reducing a warping problem. Also, an aluminum oxide film which is an insulating film is disposed between ground via plugs, thereby increasing a signal speed.

According to a method of manufacturing a semiconductor package, an aluminum oxide template is formed and a semiconductor package is manufactured using the aluminum oxide template, thereby forming a via hole having an aspect ratio of 1000:1. Therefore, a deep via hole of a fine diameter may be manufactured at a low cost, thereby reducing a manufacturing process cost. A thickness of a substrate may be formed to be large and thereby a substrate may be easily handled during a manufacturing process and production yield may be increased.

The foregoing is illustrative of the present inventive concept and is not to be construed as limiting thereof. Although a few exemplary embodiments of the present inventive concept have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. The present inventive concept is defined by the following claims, with equivalents of the claims to be included therein

What is claimed is:

1. A semiconductor package comprising:
a substrate comprising a first face and a second face, wherein the first and second faces face each other;
a first ground pattern disposed on the first face;
a second ground pattern disposed on the second face;
a plurality of ground via plugs which connect the first ground pattern and the second ground pattern, wherein the plurality of ground via plugs penetrate the substrate; and
a first aluminum oxide film interposed between the plurality of ground via plugs,
wherein a ground voltage is applied to the plurality of ground via plugs.

2. The semiconductor package of claim 1, wherein a diameter of the ground via plug is between about 10 nm and about 1 μm.

3. The semiconductor package of claim 1, further comprising:
a first signal pattern disposed on the first face and adjacent to the first ground pattern;
a second signal pattern disposed on the second face and adjacent to the second ground pattern;
a plurality of signal via plugs which penetrate the substrate and connect the first signal pattern and the second signal pattern; and
a second aluminum oxide film interposed between the plurality of signal via plugs.

4. The semiconductor package of claim 3, wherein the first ground pattern and the second ground pattern have a curved shape and substantially surround the first signal pattern and the second signal pattern, respectively, and wherein the first ground pattern and the second ground pattern vertically overlap.

5. The semiconductor package of claim 3, wherein the first signal pattern and the second signal pattern vertically overlap and have a substantially spiral shape, and
wherein the first ground pattern and the second ground pattern are disposed outside of the first signal pattern and the second signal pattern, respectively, and have the spiral shape surrounding the first signal pattern and the second signal pattern.

6. The semiconductor package of claim 5, wherein the plurality of ground via plugs are interconnected and side surfaces of the plurality of ground via plugs are coplanar, and
wherein the plurality signal via plugs are interconnected and side surfaces of the signal via plugs are coplanar.

7. The semiconductor package of claim 3, further comprising:
a first insulating film disposed on the first ground pattern, and wherein the first signal pattern is disposed on the first insulating film; and
a second insulating film, wherein the second ground pattern is disposed on the second insulating film,
wherein the second insulating film is disposed on the second signal pattern,
wherein the plurality of signal via plugs penetrate the first insulating film, the substrate and the second insulating film, and connect the first signal pattern and the second signal pattern, and
wherein the first ground pattern and the second ground pattern have a substantially circular shape and substantially surround end portions of the first signal pattern and the second signal pattern respectively.

8. The semiconductor package of claim 1, wherein the plurality of ground via plugs comprise a plurality of sub via plugs which vertically overlap.

9. The semiconductor package of claim 1, further comprising:
a plurality of dummy insulating via plugs which have a substantially same diameter as the ground via plugs, wherein the dummy insulating via plugs penetrate the substrate; and
a third aluminum oxide film interposed between the plurality of dummy insulating via plugs.

10. The semiconductor package of claim 9, wherein the plurality of dummy insulating via plug comprises one of an insulating solid and a gas.

11. The semiconductor package of claim 1, wherein the ground via plugs are disposed in a substantially honeycomb-like shape.

12. The semiconductor package of claim 1, wherein the substrate is one of an aluminum oxide template and an insulator.

13. The semiconductor package of claim 4, wherein the curved shape is substantially a C character shape.

14. A semiconductor package comprising:
a substrate comprising a first face and a second face, wherein the first and second faces face each other;
a first ground pattern disposed on the first face;
a first signal pattern disposed on the first face and spaced apart from the first ground pattern;
a second ground pattern disposed on the second face;
a second signal pattern disposed on the second face and spaced apart from the second ground pattern;
a ground via pattern which penetrates the substrate and connects the first ground pattern and the second ground pattern; and
a plurality of signal via patterns which penetrate the substrate and connect the first signal pattern and the second signal pattern,
wherein the first signal pattern, the second signal pattern and the signal via pattern vertically overlap and have a substantially spiral shape, and
wherein the first ground pattern, the second ground pattern and the ground via pattern are disposed outside of the first signal pattern, the second signal pattern and the signal via pattern and have a substantially spiral shape and substantially surrounds the first signal pattern, the second signal pattern and the signal via pattern, respectively.

15. A semiconductor package comprising:
a substrate comprising a first face and a second face which face each other;
a first ground pattern disposed on the first face;
a second ground pattern disposed on the second face;
a plurality of ground via plugs which connect the first ground pattern and the second ground pattern through the substrate;
a first aluminum oxide film interposed between the plurality of ground via plugs;
a first signal pattern disposed on the first face and adjacent to the first ground pattern;
a second signal pattern disposed on the second face and adjacent to the second ground pattern;
a plurality of signal via plugs which connect the first signal pattern and the second signal pattern through the substrate; and
a second aluminum oxide film interposed between the plurality of signal via plugs,
wherein a ground voltage is applied to the plurality of ground via plugs, and
wherein the first ground pattern and the second ground pattern have a curved shape.

16. The semiconductor package of claim 15, wherein the curved shape is substantially C-shaped.
